(19) United States
(12) Patent Application Publication
(10) Pub. No.: US 2014/0158042 A1
(43) Pub. Date: Jun. 12, 2014

(54) APPARATUS FOR FABRICATING INGOT

(71) Applicants: Seon Heo, Seoul (KR); Ji Hye Kim, Seoul (KR)

(72) Inventors: Seon Heo, Seoul (KR); Ji Hye Kim, Seoul (KR)

(73) Assignee: LG INNOTEK CO., LTD., Seoul (KR)

(21) Appl. No.: 14/235,972

(22) PCT Filed: Jul. 26, 2012
(86) PCT No.: PCT/KR2012/005989

§ 371 Date: Feb. 26, 2014

(30) Foreign Application Priority Data
Jul. 29, 2011 (KR) 10-2011-0076284

(51) Int. Cl. C30B 23/02

(52) U.S. Cl. CPC C30B 23/02
USPC 117/84; 118/728

(57) ABSTRACT

An apparatus for fabricating an ingot according to the embodiment comprises a crucible for receiving a raw material; and a seed holder for fixing a seed disposed over the raw material, wherein a buffer layer is placed between the seed holder and the seed.

### TECHNICAL FIELD

The disclosure relates to an apparatus for fabricating an ingot.

BACKGROUND ART

In general, materials are very important factors to determine the property and the performance of final products in the electric, electronic and mechanical industrial fields.

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC by using a seed, a seeded growth sublimation scheme has been suggested. In this case, after putting SiC powder serving as a raw material in a crucible, a SiC single crystal serving as a seed is provided over the raw material. In addition, the temperature gradient is formed between the raw material and the seed, so that the raw material in the crucible is diffused toward the seed and recrystallized to grow a single crystal. p Although the seed on which the single crystal is grown is attached to a specific member such as a cover of the crucible in order to perform such a process, and the attached state of the seed may exert influence on a quality of the single crystal grown from the surface of the seed. Thus, the process of attaching the seed is very important.

Specifically, due to air pores formed in an adhesive material for attaching the seed and a seed holder to each other, the single crystal may be grown from the back surface of the seed, so that a defect may occur.

### DISCLOSURE OF INVENTION

### Technical Problem

The embodiment can grow a high-quality single crystal.

### Solution to Problem

An apparatus for fabricating an ingot according to the embodiment comprises a crucible for receiving a raw material; and a seed holder for fixing a seed disposed over the raw material, wherein a buffer layer is placed between the seed holder and the seed.

### Advantageous Effects of Invention

The apparatus for fabricating the ingot according to the embodiment comprises the buffer layer between the seed and the seed holder. The buffer layer may prevent a crystal from growing from the back surface of the seed when a single crystal is grown.

That is, since the buffer layer is placed on the back surface of the seed, although air pores are formed in the adhesive layer, sublimation on the back surface of the seed may be prevented. That is, the buffer layer may prevent atoms from escaping from the seed to the air pores of the adhesive layer.

Since the buffer layer may prevent damage to the seed, the seed may be reused. Thus, the process cost may be reduced.

Further, the buffer layer may reduce the defect caused by a difference in thermal expansion coefficient between the seed holder and the seed. Further, a delamination of the seed, which may be caused by the difference in thermal expansion coefficients between the seed holder and the seed during the single crystal growth process, may be prevented.

### BRIEF DESCRIPTION OF DRAWINGS

FIG. 1 is a sectional view of an apparatus for fabricating an ingot according to an embodiment; and

FIG. 2 is an enlarged view showing a part ‘A’ of FIG. 1.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or over the other substrate, layer (or film), region, pad, or pattern, or one or more intervening layers may also be present. Such a position of the layer has been described with reference to the drawings.

Since the thickness and size of each layer shown in the drawings may be modified for the purpose of convenience or clarity of description, the size of elements does not utterly reflect an actual size.

Hereinafter, the embodiments will be described with reference to accompanying drawings.

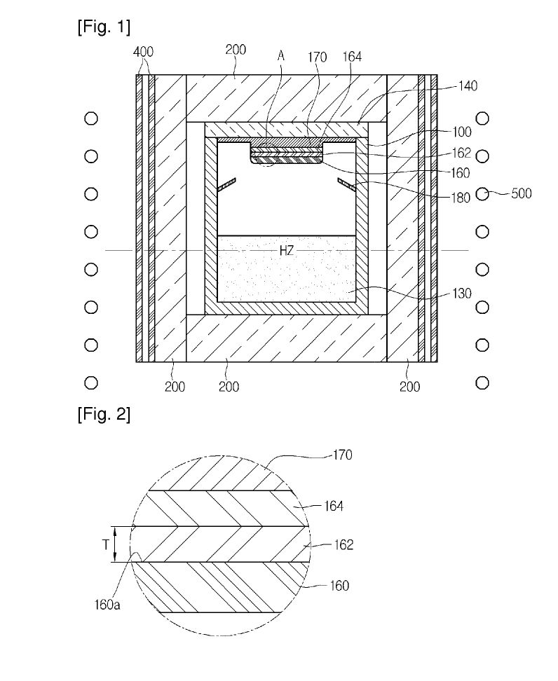

An apparatus for fabricating an ingot according to the first embodiment will be described in detail with reference to FIGS. 1 and 2. FIG. 1 is a sectional view of the apparatus for fabricating the ingot according to the embodiment. FIG. 2 is an enlarged view showing a part ‘A’ of FIG. 1.

Referring to FIGS. 1 and 2, the apparatus for fabricating the ingot according to the embodiment comprises a crucible 100, an upper cover 140, a seed holder 170, a buffer layer 162, a focusing tube 180, a thermal insulator 200, a quartz tube 400, and a heat generation induction part 500.

The crucible 100 may receive a raw material 130 therein. The raw material 130 may comprise silicon and carbon. In more detail, the raw material 130 may comprise a silicon carbide compound. The crucible 100 may receive silicon carbide (SiC) powder or polycarbosilane therein.

The crucible 100 may have a cylindrical shape such that the crucible 100 can receive the raw material 130 therein.

The crucible 100 may comprise a material having a melting point equal to or higher than the sublimation temperature of silicon carbide.

For example, the crucible 100 may be formed by using graphite.

Further, a material having a melting point equal to or higher than the sublimation temperature of silicon carbide may be coated on the graphite of the crucible 100. A material chemically inactive with silicon and hydrogen at the temperature, at which silicon carbide single crystal 190 is grown, is preferably used as the material coated on the graphite. For example, metal carbide or metal nitride may be used. Specifically, a mixture including at least two of Ta, Hf, Nb, Zr, W and V and carbide including carbon may be coated. Further, a mixture including at least two of Ta, Hf, Nb, Zr, W and V and nitride including nitrogen may be coated.

Then, the upper cover 140 may be placed at an upper portion of the crucible 100. The upper cover 140 may seal the crucible 100. The upper cover 140 may seal the crucible 100, such that reaction can occur in the crucible 100.

The upper cover 140 may comprise graphite. However, the embodiment is not limited thereto, and the upper cover 140 may comprise a material having a melting point which is equal to or higher than the sublimation temperature of silicon carbide.

The seed holder 170 is placed at the lower end portion of the upper cover 140. That is, the seed holder 170 is disposed over the raw material 130.

The seed holder 170 may fix the seed 160. The seed holder 170 may comprise high-density graphite.

An adhesive layer 164 may be placed between the seed holder 170 and the seed 160. In detail, the adhesive layer 164 may be placed between the seed holder 170 and the buffer layer 162. The adhesive layer 164 may make contact with the buffer layer 162. The adhesive layer 164 may attach the seed 160 to the seed holder 170.

The adhesive layer 164 may comprise carbon C. As one example, the adhesive layer 164 may comprise sugar or graphite. The sugar or graphite is changed into carbon. Those materials have good adhesiveness. Thus, the adhesive layer 164 may stably attach the seed 160 to the seed holder 170.

The buffer layer 162 may be placed the seed holder 170 and the seed 160. In detail, the buffer layer 162 may be placed between the adhesive layer 164 and the seed 160. The seed 160 may comprise a back surface 160a facing the seed holder 170, and the buffer layer 162 may be placed on the back surface 160a. The buffer layer 162 may be placed on the entire back surface 160a.

The buffer layer 162 may comprise a material having a melting point equal to or higher than the ingot growth temperature. The buffer layer 162 may comprise metal. The buffer layer 162 comprises at least one selected from the group consisting of tantalum (Ta), hafnium (Hf), niobium (Nb), zirconium (Zr) and tungsten (W).

The buffer layer 162 has a thickness T in the range of 10 nm to 1 mm.

The buffer layer 162 may be formed by coating. A metal material may be coated on the back surface of the seed 160. For example, the buffer layer 162 may be formed through a chemical vapor deposition (CVD) or a sputtering process.

When the single crystal is grown, the buffer layer 162 may prevent a crystal from growing from the back surface.

In detail, while the adhesive layer 164 is carbonized at a high temperature which is a single crystal growth temperature, air pores are comprised in the adhesive layer 164. Although the sizes of the air pores are small, a temperature gradient occurs between the seed 160 and the seed holder 170 in the vertical direction. Due to the temperature gradient, sublimation may occur on the back surface of the seed 160. That is, silicon carbide atoms of the seed 160 may escape through the air pores. A fine tube, defects and a space may be created at the portions from which the silicon carbide atoms escape. Thus, the seed 160 may be damaged. Further, those defects gradually propagate into the single crystal grown from the seed 160, so that the quality of the single crystal may deteriorate. Further, the product yield of the single crystal may be reduced.

However, according to the embodiment, since the buffer layer 162 is placed on the back surface 160a of the seed 160, although the air pores are formed in the adhesive layer 164, the sublimation of the back surface 160a of the seed 160 may be prevented. That is, the buffer layer 162 may prevent the atoms of the seed 160 from escaping into the air pores of the adhesive layer 164.

Therefore, the buffer layer 162 is uniformly formed on the entire back surface 160a of the seed 160, so that the seed 160 may not make contact with the adhesive layer 164. That is, the back surface 160a of the seed 160 may not be exposed through the buffer layer 162.

The buffer layer 162 may prevent the seed 160 from being damaged, so that the seed 160 may be reused. Thus, the process cost may be reduced.

Further, the buffer layer may diminish the defect caused by a difference in thermal expansion coefficients between the seed holder and the seed. Further, delamination phenomenon of the seed 160, which may be caused by the difference in thermal expansion coefficient between the seed holder and the seed during the single crystal growth process, may be prevented.

The focusing tube 180 is placed in the crucible 100. The focusing tube 180 may be placed at a portion on which the single crystal is grown. The focusing tube 180 narrows a transfer passage of a sublimated silicon carbide gas, such that diffusion of the sublimated silicon carbide is concentrated on the seed 170. Thus, a growth rate of the single crystal may be increased.

The thermal insulator 200 surrounds the crucible 100. The thermal insulator 200 maintains the temperature of the crucible 100 at the crystal growth temperature. Since the crystal growth temperature of silicon carbide is very high, graphite felt may be used for the thermal insulator 200. In detail, the graphite felt used for the thermal insulator 200 may be manufactured in a cylindrical shape at a predetermined thickness by pressing a graphite fiber. Further, the thermal insulator 200 may be formed in a plurality of layers, so that the thermal insulator 200 may surround the crucible 100.

The quartz tube 400 is placed at a peripheral surface of the crucible 100. The quartz tube 400 is fitted around the peripheral surface of the crucible 100. The quartz tube 400 may prevent heat from transferring from the heat generation induction part 500 to the inside of the single crystal growth apparatus. The quartz tube 400 may be a hollow tube having an empty inner space. Cooling water may be circulated through the inner space of the quartz tube 400. Thus, the quartz tube 400 may more exactly control a growth rate and a growth size of the single crystal.

The heat generation induction part 500 is placed out of the crucible 100. For example, the heat generation induction part 500 may be a high-frequency induction coil. The crucible 100 may be heated as a high-frequency current flows through the high-frequency induction coil. That is, the raw material, which is received in the crucible 100, may be heated at the desired temperature.

The central area of the heat generation induction part 500, which is induction heated, is formed at a position lower than the central area of the crucible 100. Thus, the temperature gradient may be formed in the crucible 100 such that an upper portion and a low portion of the crucible 100 may have temperatures different from each other. That is, a hot zone (HZ), which is the center of the heat generation induction part 500, is located lower than the center of the crucible 100, so that the temperature of the low portion of the crucible 100 is higher than that of the upper portion of the crucible 100 about the hot zone (HZ). Further, the temperature becomes high from the central area to the outer peripheral portion of the crucible 100. Due to the temperature gradient, the silicon carbide raw material is sublimated and the sublimated silicon carbide gas moves to a surface of the seed 170 having the relatively low temperature. Thus, the silicon carbide gas is grown in a single crystalline structure 190 through the recrystallization.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible for receiving a raw material; and
a seed holder for fixing a seed disposed over the raw material,
wherein a buffer layer is placed between the seed holder and the seed.

2. The apparatus of claim 1, wherein an adhesive layer is further placed between the seed holder and the seed.

3. The apparatus of claim 2, wherein the seed comprises a back surface facing the seed holder and the buffer layer is placed on the back surface.

4. The apparatus of claim 1, wherein the buffer layer comprises at least one selected from the group consisting of tantalum (Ta), hafnium (Hf), niobium (Nb), zirconium (Zr) and tungsten (W).

5. The apparatus of claim 1, wherein the buffer layer has a thickness in a range of 10 nm to 1 mm.

6. The apparatus of claim 1, wherein the seed comprises silicon carbide.

7. The apparatus of claim 1, wherein the adhesive layer comprises sugar or graphite.

8. The apparatus of claim 1, wherein the adhesive layer comprises an air pore.

9. A method for fabricating an ingot, the method comprising:
preparing a crucible for receiving a raw material;
disposing a seed holder for fixing a seed over the raw material; and
growing an ingot from the raw material,
wherein a buffer layer is placed between the seed holder and the seed.

10. The method of claim 9, wherein an adhesive layer including carbon (C) is further placed between the seed holder and the seed and the buffer layer is placed between the adhesive layer and the seed.

11. The method of claim 9, wherein the buffer layer comprises at least one selected from the group consisting of tantalum (Ta), hafnium (Hf), niobium (Nb), zirconium (Zr) and tungsten (W).

12. The apparatus of claim 2, wherein the buffer layer is placed between the adhesive layer and the seed.

13. The apparatus of claim 3, wherein the buffer layer is placed over an entire area of the back surface of the seed.

14. The apparatus of claim 1, wherein the buffer layer directly makes contact with the seed.

15. The apparatus of claim 1, wherein the buffer layer comprises a material having a melting point which is equal to or higher than an ingot growth temperature.

16. The apparatus of claim 1, wherein the buffer layer comprises metal.

17. The apparatus of claim 1, wherein the seed holder comprises graphite.

18. The apparatus of claim 1, wherein the adhesive layer comprises carbon (C).
